(19) United States
(12) Patent Application Publication
(10) Pub. No.: US 2016/0372437 A1
(43) Pub. Date: Dec. 22, 2016

(54) SEMICONDUCTOR PACKAGE

(71) Applicant: SK hynix Inc., Icheon-si Gyeonggi-do (KR)

(72) Inventor: Jae Hong JEONG, Yongin-si Gyeonggi-do (KR)

(21) Appl. No.: 15/254,670

(22) Filed: Sep. 1, 2016

Related U.S. Application Data
(62) Division of application No. 14/517,204, filed on Oct. 17, 2014.

(30) Foreign Application Priority Data
Jun. 26, 2014 (KR) 10-2014-0078681

(51) Int. Cl. H01L 23/00

(52) U.S. Cl. CPC H01L 24/16; H01L 24/08; H01L 2224/0801; H01L 2224/08113; H01L 2224/08501; H01L 2224/08505; H01L 2224/16012; H01L 2224/16059; H01L 2224/16104

(57) ABSTRACT

A semiconductor package including a first metal layer configured for use as a bonding pad, a second metal layer formed over the first metal layer, and the second metal layer having a separation allowing for the second metal layer to be positioned above distal ends of the first metal layer. The semiconductor package also including a third metal layer formed over the second metal layer, and the third metal layer having a separation allowing for the third metal layer to be positioned above distal ends of the first metal layer, a trench defined by the separation of the third metal layer and second metal layer, and extending through the third metal layer and the second metal layer to expose the first metal layer, and a bonding ball located within the trench.

### CROSS-REFERENCES TO RELATED APPLICATION

The present application is a division of U.S. application Ser. No. 14/517,204, filed on Oct. 17, 2014, and the present application claims priority under 35 U.S.C. §119(a) to Korean application number 10-2014-0078681, filed on Jun. 26, 2014, in the Korean Intellectual Property Office, which is incorporated herein by reference in its entirety.

### BACKGROUND

### 1. Technical Field

Various embodiments generally relate to a semiconductor package, and more particularly, to the structure of a pad which connects a semiconductor device and an external pin.

### 2. Related Art

These days, the electronic industry trends to manufacture products with high reliability at reduced costs in such a way as to accomplish light weight, miniaturization, high speed operation, multi-functionality and high performance. A package assembly technology is considered to be one of the most important technologies for achieving the purposes involved in designing such products.

The package assembly technology is a technology that focuses on protecting a semiconductor chip, formed with integrated circuits, from external circumstances. The package assembly technology is also a technology that focuses on easily mounting the semiconductor chip to a substrate, through a wafer assembly process, so as to secure the operational reliability of the semiconductor chip.

In the conventional art, packages are manufactured by cutting a wafer to separate individual semiconductor chips from one another and then performing a packaging process for the individual semiconductor chips. However, the packaging process includes in itself a number of unit processes. These unit processes may include processes for chip attachment, wire bonding, molding, trimming and forming. In the conventional package manufacturing method in which the packaging process should be performed for the respective semiconductor chips, a problem may be encountered. The problem encountered often deals with the substantially long times required for packaging all of the semiconductor chips when considering the number of semiconductor chips which are obtained from one wafer.

In this situation, recently, the technology of wafer level chip scale packages has been suggested. In wafer level chip scale packages assembly is not performed with individual semiconductor chips separated from one another, rather a redistribution work and formation of ball-shaped external connection terminals are performed at a wafer level. Then the individual semiconductor chips are separated.

What follows is a brief description concerning a method for manufacturing the wafer level chip scale packages. First, a wafer is first formed, then a first insulation layer is formed to expose bonding pads disposed on the top surfaces of semiconductor chips, and finally redistribution lines are formed on the first insulation layer to be individually connected with the bonding pads.

Then, a second insulation layer is formed on the first insulation layer and the redistribution lines in such a way as to partially expose the redistribution lines, and external connection terminals such as solder balls are attached to the redistribution lines which are exposed. Thereafter, the wafer formed with the external connection terminals is cut to a chip level completing the manufacture of the wafer level chip scale packages.

In a semiconductor device, pads serve as parts which are connected with external wires. In this regard, in the case of performing wire bonding for the semiconductor device, a fail may occur in that the junction surface of a pad may be disconnected during the process of working on the semiconductor device.

For example, in the case of applying a flip chip, the bonding portion of a ball structure is connected with a pad. However, when filling a mold during a packaging process, the ball is likely to be disconnected from the pad. Also, even in the case of connecting a pad through the use of wire bonding, the pad and a wire are likely to be disconnected from each other.

A wire bonding process is a process that involves connecting bonding pads of a semiconductor chip and leads of a lead frame by using wires. This wire bonding process allows the electrical characteristics of the semiconductor chip to be transferred to a circuit board.

In the bonding process, a fail may generally occur due to poor adhesion between a wire and a bonding pad or a lead, a crack by an interlayer stress, absorption of moisture, or a peel-off. That is to say, in the case of electrically connecting elements in a semiconductor package through wire bonding, electrical connections may become unstable due to bending, protrusion and snapping of bonding wires.

### SUMMARY

In an embodiment, a semiconductor package may include: a first metal layer configured for use as a bonding pad; a second metal layer formed over the first metal layer, and separated to be positioned on both sides in view of the first metal layer; a third metal layer formed over the second metal layer, and separated to be positioned on both sides in view of the first metal layer; and a trench defined through the third metal layer and the second metal layer to expose the first metal layer, and having buried therein a bonding ball.

In an embodiment, a semiconductor package including a first metal layer configured for use as a bonding pad, a second metal layer formed over the first metal layer, and the second metal layer having a separation allowing for the second metal layer to be positioned above distal ends of the first metal layer. The semiconductor package also including a third metal layer formed over the second metal layer, and the third metal layer having a separation allowing for the third metal layer to be positioned above distal ends of the first metal layer, a trench defined by the separation of the third metal layer and second metal layer, and extending through the third metal layer and the second metal layer to expose the first metal layer, and a bonding ball located within the trench.

In an embodiment, a semiconductor package may include a first metal layer, and a second metal layer configured for use as a bonding pad and formed over the first metal layer. The semiconductor package may also include a plurality of third metal layer parts formed over the second metal layer, and separated from one another by gaps. The semiconductor package may include a pad open region exposing the second metal layer through spaces defined between the plurality of third metal layer parts, and a bonding ball configured to bury the pad open region.

In an embodiment, a semiconductor package may include a first metal layer used as a bonding pad, a plurality of second metal layer parts formed over the first metal layer, and separated from one another by a predetermined gap. The semiconductor package may also include a plurality of third metal layer parts formed over the second metal layer parts, and separated from one another by a preselected gap. The semiconductor package may include a pad open region exposing the first metal layer through spaces defined between the plurality of third metal layer parts and between the plurality of second metal layer parts, and a bonding ball positioned to bury the pad open region.

### BRIEF DESCRIPTION OF THE DRAWINGS

FIG. 1 is a view illustrating a representation of a semiconductor package.

FIG. 2 is a view illustrating an example of a representation of a semiconductor package in accordance with an embodiment.

FIGS. 3a to 3d are views illustrating an example of a representation of a semiconductor package in accordance with an embodiment.

FIGS. 4a and 4b are views illustrating an example of a representation of a semiconductor package in accordance with an embodiment.

FIG. 5 illustrates a block diagram of an example of a representation of a system employing the semiconductor package in accordance with the embodiments discussed above with relation to FIGS. 1-4.

### DETAILED DESCRIPTION

Hereinafter, a semiconductor package will be described below with reference to the accompanying drawings through various examples of embodiments.

Various embodiments may generally relate to a semiconductor package, and more particularly, to a technology for possibly improving the structure of a pad which connects a semiconductor device and an external pin.

Various embodiments may be directed to the technology of changing the structure of a pad junction surface. For example, the pad junction surface may be widened, thereby reducing electrical resistance and perhaps strengthening the physical junction between a pad and a bonding ball.

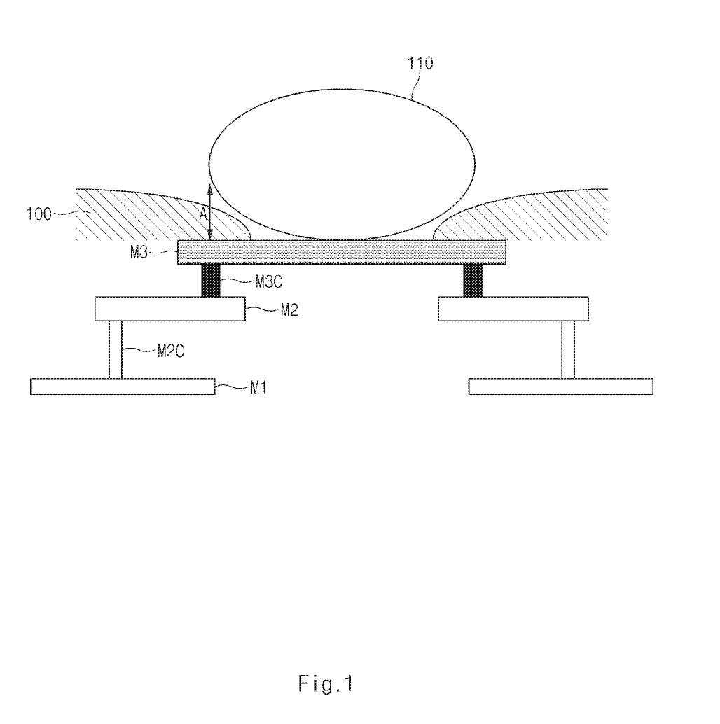

FIG. 1 is a view illustrating a representation of a semiconductor package.

A semiconductor package may include a first metal layer M1, contact lines M2C, a second metal layer M2, contact lines M3C, a third metal layer M3, an insulation layer 100, and a bonding ball 110.

The second metal layer M2 connected with the contact lines M2C may be formed over the first metal layer M1. The first metal layer M1 may be separated or divided in such a way as to be positioned on both sides of the third metal layer M3. The first metal layer M1 may be separated into two distinct parts or more. The first metal layer M1 may be formed over either the distal ends or both ends of the third metal layer M3. Each separated section of the first metal layer M1 may be connected with the respective contact lines M2C. The contact lines M2C may connect the first metal layer M1 to the second metal layer M2. The contact lines M2C may connect the first metal layer M1 to the second metal layer M2 forming contact nodes.

The third metal layer M3 connected with the contact lines M3C may be formed over the second metal M2. The second metal layer M2 may be separated or divided in such a way as to be positioned on both sides of the third metal layer M3. The second metal layer M2 may be divided into two distinct parts or more. The second metal layer M2 may be formed over either the distal ends or both ends of the third metal layer M3. Each separated section of the second metal layer M2 may be connected with the respective contact lines M3C. The contact lines M3C may connect the third metal layer M3 to the second metal layer M2. The contact lines M3C may connect the third metal layer M3 to the second metal layer M2 forming contact nodes. The insulation layer 100 and the bonding ball 110 are formed on or above the third metal layer M3.

The third metal layer M3 may be exposed through the insulation layer 100. The third metal layer M3 may include a bonding pad. An external connection terminal such as the bonding ball 110 may be attached to the exposed portion of the third metal layer M3 while being formed on portions of the insulation layer 100 which adjoins the exposed portion of the third metal layer M3. The depth of a trench in which the bonding ball 110 is buried between the opposite portions of the insulation layer 100 to be connected with the third metal layer M3 is designated by the reference symbol A as illustrated in FIG. 1.

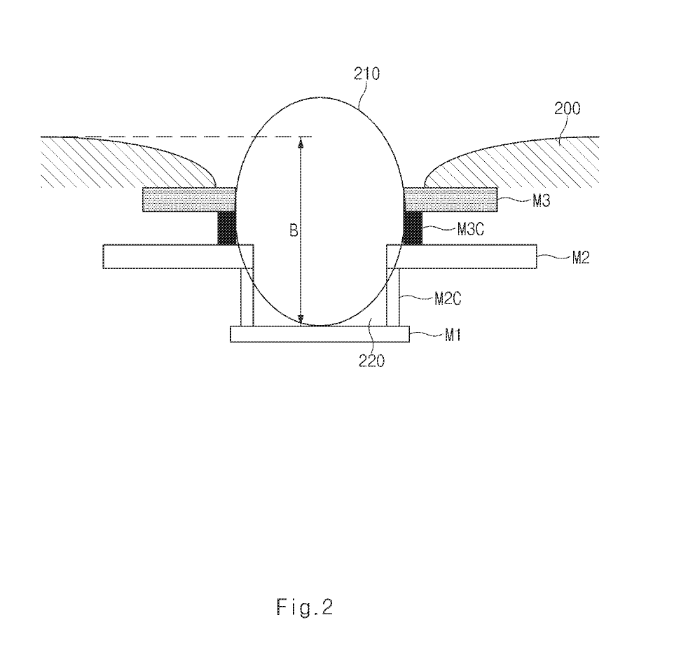

FIG. 2 is a view illustrating an example of a representation of a semiconductor package in accordance with an embodiment.

A semiconductor package in accordance with an embodiment may include a first metal layer M1, contact lines M2C, a second metal layer M2, contact lines M3C, a third metal layer M3, an insulation layer 200, and a bonding ball 210.

The second metal layer M2 may be connected with the contact lines M2C and may be formed over the first metal layer M1. The contact lines M2C may be formed on both sides of the first metal layer M1, and are connected with portions of the second metal layer M2, respectively. The contact lines M2C may be formed on distal ends of the first metal layer M1, and may be connected with portions of the second metal layer M2, respectively. Portions of the second metal layer M2 may be spaced apart from other portions of the second metal layer M2. The second metal layer M2 may be divided into two distinct portions or more.

The third metal layer M3 may be connected with the contact lines M3C and may be formed over the second metal layer M2. The second metal layer M2 may be separated or divided in such a way as to be positioned on both sides of the first metal layer M1. The second metal layer M2 may be formed over either the distal ends or both ends of the first metal layer M1. Each separated section of the second metal layer M2 may be connected with the respective contact lines M2C. The contact lines M2C may connect the first metal layer M1 to the second metal layer M2. The contact lines M2C may connect the first metal layer M1 to the second metal layer M2 forming contact nodes.

The third metal layer M3 may be separated or divided in such a way as to be positioned on both sides of the first metal layer M1. The third metal layer M3 may be divided into two distinct portions or more. The third metal layer M3 may be formed over either the distal ends or both ends of the first metal layer M1. Each separated section of the third metal layer M3 may be connected with the respective contact lines M3C. The contact lines M3C may connect the third metal layer M3 to the second metal layer M2. The contact lines M3C may connect the third metal layer M3 to the second metal layer M2 forming contact nodes. The insulation layer 200 may be formed on or above the third metal layer M3.

The first metal layer M1 may be underlying beneath the insulation layer 200, the third metal layer M3 and the second metal layer M2. The first metal layer M1 which is underlying may be exposed through the insulation layer 200, the third metal layer M3 and the second metal layer M2. The insulation layer 200, the third metal layer M3 and the second metal layer M2 may be overlying above the first metal layer M1. The first metal layer M1 may include or comprise a bonding pad.

A trench 220 may be defined by the insulation layer 200, the third metal layer M3 and the second metal layer M2, and may be formed in such a way as to expose the first metal layer M1. An external connection terminal such as for example a bonding ball 210 may be inserted into the trench 220. The bottom surface of the bonding ball 210 may be attached to the first metal layer M1. The side surfaces of the bonding ball 210 may be connected with the surfaces of the second metal layer M2 and the third metal layer M3. The side surfaces of the bonding ball 210 may also be connected with the side surfaces of the second metal layer M2 and the side surfaces of the third metal layer M3 created by the separations in the respective layers.

The depth of the trench 220 which is defined through the insulation layer 200, the third metal layer M3 and the second metal layer M2 and in which the bonding ball 210 is buried to be connected with the first metal layer M1 is designated by the reference symbol B. In an embodiment illustrated in FIG. 2, the depth B of the trench 220, in which the bonding ball 210 is buried, may be deeper than the depth A discussed above and illustrated in FIG. 1.

In an embodiment, the trench 220 may be defined by the separation between both the second metal layer M2 and the third metal layer M3, each layer divided and positioned on both sides of the first metal layer M1, in such a way as to expose the first metal layer M1 lying lowermost. The bonding ball 210 may be buried in the trench 220, and may be in contact with the first metal layer M1.

The bonding ball 210 may be buried relatively deep in the trench 220. Thus, the probability of the bonding ball 210 being disconnected, when for example introducing a material for molding a package, may be decreased. Further, in the cases where the bonding ball 210 is buried relatively deep in the trench 220 an additional advantage may be provided in that resistance may be reduced. This may be because the contact area between the bonding ball 210 and the metal layers M1, M2 and M3 is increased when compared to the cases where junction is made two-dimensionally.

Moreover, in the cases of wire bonding, in the conventional art, the first metal layer M1 is likely to be pushed and lifted by a bonding pressure. However, in an embodiment, since the first metal line M1 is secured not to be pushed leftward or rightward because of the defined area of the trench 220 between the second metal layer M2 and the third metal layer M3, a more stable junction between a wire and the first metal layer M1 may be possible.

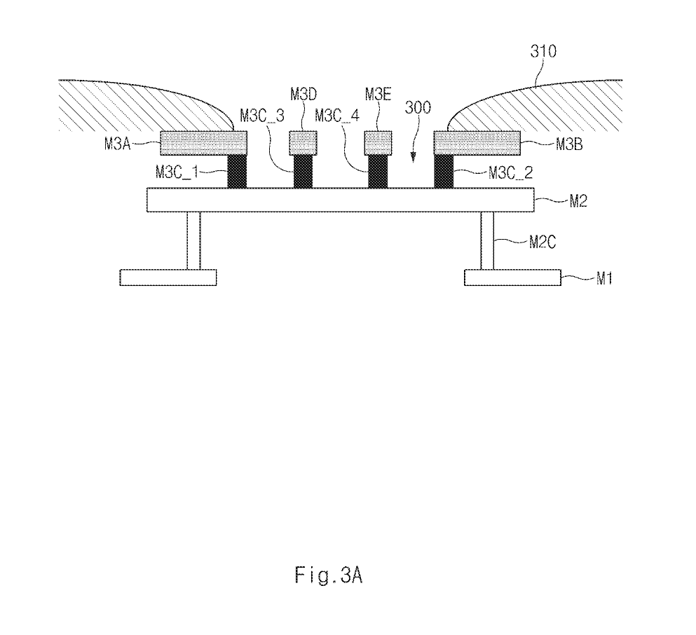

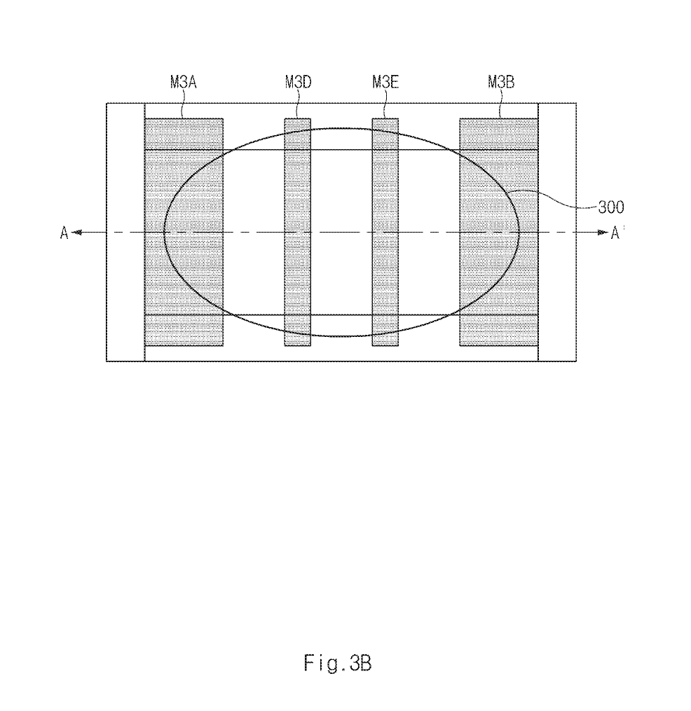

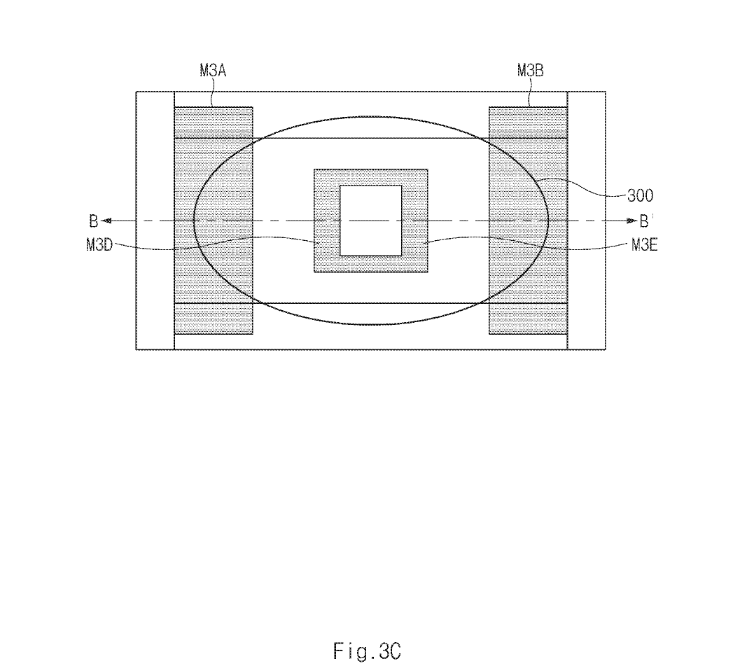

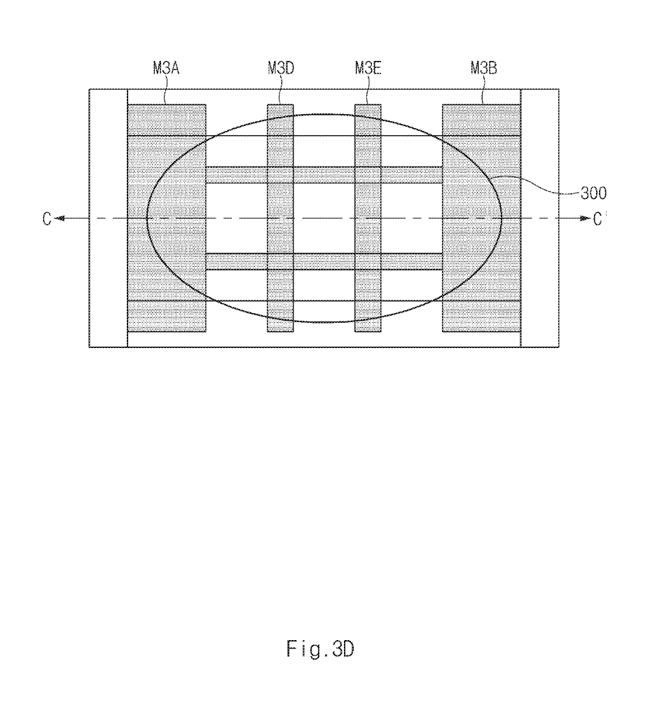

FIGS. 3a to 3d are views illustrating an example of a representation of a semiconductor package in accordance with an embodiment. FIG. 3a is a cross-sectional view taken along the line A-A′ of FIG. 3b. Also, FIG. 3a may be a cross-sectional view taken along the line B-B′ of FIG. 3c. Further, FIG. 3a may be a cross-sectional view taken along the line C-C′ of FIG. 3d.

A semiconductor package in accordance with an embodiment may include a first metal layer M1, contact lines M2C, and a second metal layer M2. The semiconductor package may also include a plurality of contact lines M3C_1 to M3C_4, a plurality of third metal layer parts M3A, M3B, M3D and M3E, a pad open region 300, and an insulation layer 310.

The second metal layer M2 may be connected with the contact lines M2C and may be formed over the first metal layer M1. The second metal layer M2 may include a bonding pad. The first metal layer M1 may be separated or divided in such a way as to be positioned on both sides of the second metal layer M2. Each separated section of the first metal layer M1 may be connected with the respective contact lines M2C. The contact lines M2C may connect the first metal layer M1 to the second metal layer M2. The contact lines M2C may connect the first metal layer M1 to the second metal layer M2 forming contact nodes.

The plurality of contact lines M3C_1 to M3C_4 are formed on the second metal layer M2. The plurality of third metal layer parts M3A, M3B, M3D and M3E, the number of which corresponds to the number of the plurality of contact lines M3C_1 to M3C_4, may be formed on the plurality of contact lines M3C_1 to M3C_4. The second metal layer M2 may be formed in a type of a single line such that the plurality of contact lines M3C_1 to M3C_4 may be arranged on the second metal layer M2.

The plurality of contact lines M3C_1 to M3C_4 may be formed on the second metal layer M2 in such a way as to be separated from one another by a predetermined gap. The plurality of contact lines M3C_1 to M3C_4, which are formed to be separated from one another by the predetermined gap, define a plurality of slits in the cross-sectional view. The plurality of third metal layer parts M3A, M3B, M3D and M3E may be formed on the plurality of contact lines M3C_1 to M3C_4 to be correspondingly connected with the plurality of contact lines M3C_1 to M3C_4. The insulation layer 310 may be formed on the third metal layer parts M3A and M3B which are disposed at outermost sides among the plurality of third metal layer parts M3A, M3B, M3D and M3E.

The pad open region 300 may be defined between the plurality of third metal layer parts M3A, M3B, M3D and M3E and between the plurality of contact lines M3C_1 to M3C_4 in such a way as to expose the second metal layer M2. The pad open region 300 may be defined by the spaces between the plurality of third metal layer parts M3A, M3B, M3D and M3E and between the plurality of contact lines M3C_1 to M3C_4. An external connection terminal such as a bonding ball may be buried in the pad open region 300.

In the pad open region 300, the bottom surface of the bonding ball may be connected to the exposed portions of the second metal layer M2. Further, the bonding ball may be connected with the side surfaces of the third metal layer parts M3A and M3B which are disposed at the outermost sides among the plurality of third metal layer parts M3A, M3B, M3D and M3E and with both side surfaces and the top surfaces of the third metal layer parts M3D and M3E which are disposed centrally among the plurality of third metal layer parts M3A, M3B, M3D and M3E.

In the cases where the plurality of third metal layer parts M3A, M3B, M3D and M3E and the plurality of contact lines M3C_1 to M3C_4 are formed in the shape of prominences and depressions as illustrated in FIG. 3a, the stable junction of the bonding ball may be possible since a contact area over which the bonding ball is connected is increased.

FIG. 3b is the plan view of FIG. 3a. In an embodiment, as illustrated in FIG. 3b, the two third metal layer parts M3A and M3B, which are disposed at the outermost sides among the plurality of third metal layer parts M3A, M3B, M3D and M3E, may be disposed as a type of line configuration. Moreover, the two third metal layer parts M3D and M3E, which are disposed centrally among the plurality of third metal layer parts M3A, M3B, M3D and M3E, may be disposed as a type of lines parallel or substantially parallel to the third metal layer parts M3A and M3B. The third metal layer parts disposed centrally M3D and M3E among the plurality of third metal layer parts M3A, M3B, M3D and M3E may be disposed on the corresponding first contact nodes M3C_3 and M3C_4, and may be arranged in lines.

The thicknesses of the third metal layer parts M3A and M3B may be the same with each other. The thicknesses of the third metal layer parts M3D and M3E may be the same with each other. The third metal layer parts M3A and M3B may be thicker than the third metal layer parts M3D and M3E.

FIG. 3c is the plan view of FIG. 3a and illustrates an embodiment. In an embodiment, referring to FIG. 3c, the two third metal layer parts M3A and M3B, which are disposed at the outermost sides among the plurality of third metal layer parts M3A, M3B, M3D and M3E, may be disposed as a type of lines. Moreover, the two third metal layer parts M3D and M3E, which are disposed centrally among the plurality of third metal layer parts M3A, M3B, M3D and M3E, may be disposed as a type of square, rectangle or quadrangle. The square, rectangle, or quadrangle may have openings therein as illustrated in for example FIG. 3C. It may be that the two third metal layer parts M3D and M3E, which are separately illustrated on the cross-sectional view, are connected with each other on the plan view. The third metal layer parts disposed centrally M3D and M3E among the plurality of third metal layer parts M3A, M3B, M3D and M3E may be disposed on the corresponding first contact nodes M3C_3 and M3C_4, and may be arranged to form substantially the shape of a quadrangle as illustrated, for example, in FIG. 3c.

FIG. 3d is the plan view of FIG. 3a and illustrates an embodiment. In an embodiment, referring to FIG. 3d, the two third metal layer parts M3A and M3B, which are disposed at the outermost sides among the plurality of third metal layer parts M3A, M3B, M3D and M3E, may be disposed as a type of lines. Moreover, the third metal layer parts M3D and M3E, which are disposed centrally among the plurality of third metal layer parts M3A, M3B, M3D and M3E, may be disposed as a type of mesh-shaped lattice. The third metal layer parts disposed centrally M3D and M3E among the plurality of third metal layer parts M3A, M3B, M3D and M3E may be disposed on the corresponding first contact nodes M3C_3 and M3C_4, and may be arranged to form substantially the shape of a mesh-shaped lattice as illustrated, for example, in FIG. 3d.

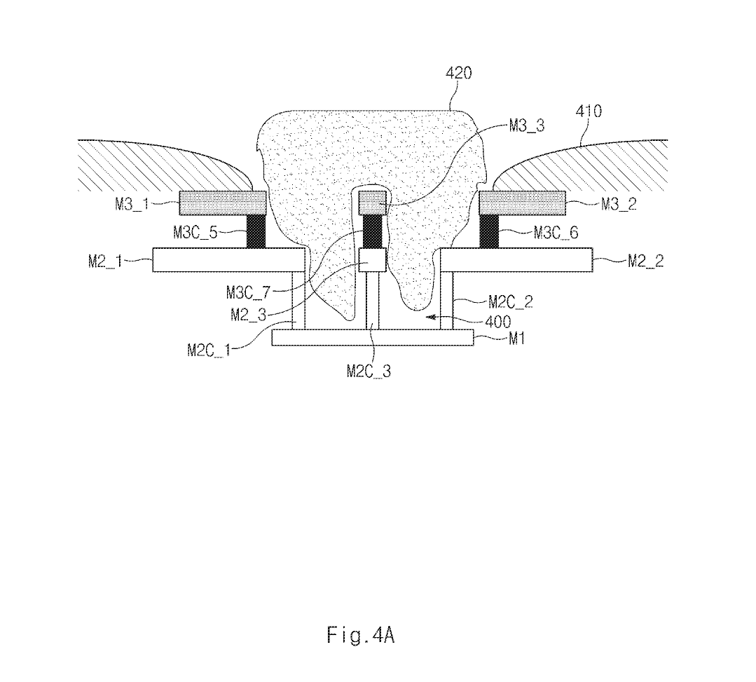

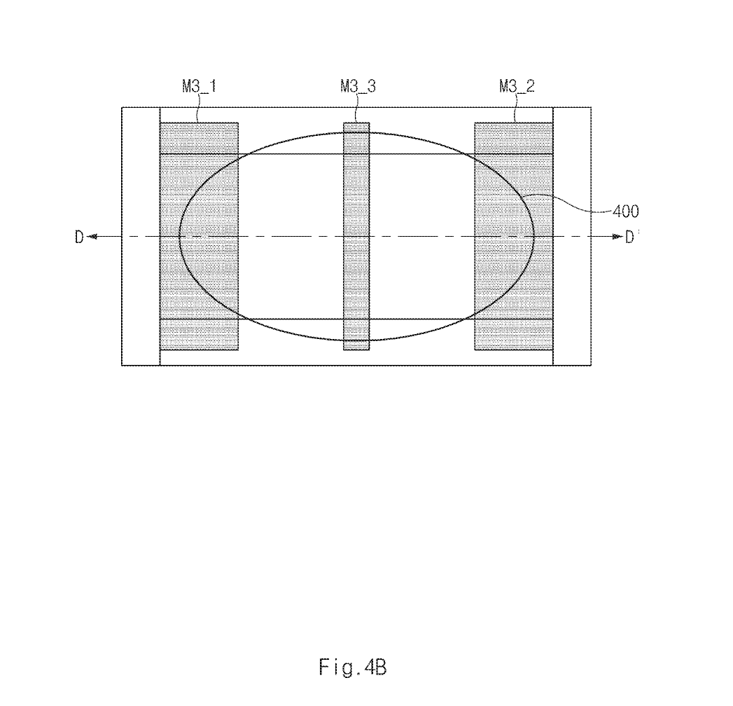

FIGS. 4a and 4b are views illustrating an example of a representation of a semiconductor package in accordance with an embodiment. FIG. 4a is a cross-sectional view taken along the line D-D′ of FIG. 4b.

The semiconductor package according to an embodiment of FIG. 4a may include a first metal layer M1, a plurality of contact lines

M2C_1 to M2C_3, a plurality of second metal layer parts M2_1 to M2_3, a plurality of contact lines M3C_5 to M3C_7, and a plurality of third metal layer parts M3_1 to M3_3. The semiconductor package may also include a pad open region 400, an insulation layer 410, and a bonding ball 420.

The plurality of contact lines M2C_1 to M2C_3 may be formed on the first metal layer M1. The plurality of contact lines M2C_1 to M2C_3 may be formed on the first metal layer M1 in such a way as to be separated from one another by a predetermined gap. The plurality of contact lines M2C_1 to M2C_3, which are formed to be separated from one another by the predetermined gap, define a plurality of slits in the cross-sectional view.

The plurality of second metal layer parts M2_1 to M2_3, the number of which corresponds to the number of the plurality of contact lines M2C_1 to M2C_3, are formed on the plurality of contact lines M2C_1 to M2C_3. The first metal layer M1 may comprise a bonding pad. The first metal layer M1 may be formed as a type of a single line such that the plurality of contact lines M2C_1 to M2C_3 may be arranged on the first metal layer M1.

The plurality of contact lines M3C_5 to M3C_7 may be formed on the plurality of second metal layer parts M2_1 to M2_3. The plurality of third metal layer parts M3_1 to M3_3, the number of which corresponds to the number of the plurality of contact lines M3C_5 to M3C_7, may be formed on the plurality of contact lines M3C_5 to M3C_7.

The plurality of contact lines M3C_5 to M3C_7 may be formed on the plurality of second metal layer parts M2_1 to M2_3 in such a way as to be separated from one another by a preselected gap. The plurality of contact lines M3C_5 to M3C_7, which are formed to be separated from one another by the preselected gap, define a plurality of slits in the cross-sectional view. The plurality of third metal layer parts M3_1 to M3_3 are formed on the plurality of contact lines M3C_5 to M3C_7 to be correspondingly connected with the plurality of contact lines M3C_5 to M3C_7. The insulation layer 410 may be formed on the third metal layer parts M3_1 and M3_2 which are disposed at outermost sides among the plurality of third metal layer parts M3_1 to M3_3.

The contact lines M2C_1 to M2C_3 may connect the first metal layer M1 to the second metal layers M2_1 to M2_3, respectively. The contact lines M2C_1 to M2C_3 may connect the first metal layer M1 to the second metal layers M2_1 to M2_3 forming contact nodes. The contact lines M3C_5 to M3C_7 may connect the second metal layer parts M2C_1 to M2C_3 to the third metal layer parts M3_1 to M3_3, respectively. The contact lines M3C_5 to M3C_7 may connect the second metal layer parts M2C_1 to M2C_3 to the third metal layer parts M3_1 to M3_3 forming contact nodes.

The pad open region 400 may be defined between the plurality of third metal layer parts M3_1 to M3_3, between the plurality of contact lines M3C_5 to M3C_7, between the plurality of second metal layer parts M2_1 to M2_3, and between the plurality of contact lines M2C_1 to M2C_3 in such a way as to expose the first metal layer M1. An external connection terminal such as the bonding ball 420 may be buried in the pad open region 400.

In the pad open region 400, the bottom surface of the bonding ball 420 may be connected to the exposed portions of the first metal layer M1. The side surfaces of the plurality of third metal layer parts M3_1 to M3_3, the plurality of contact lines M3C_5 to M3C_7, the plurality of second metal layer parts M2_1 to M2_3 and the plurality of contact lines M2C_1 to M2C_3 may be connected with the bonding ball 420. The bonding ball 420 may be formed to cover the top surface of the third metal layer part M3_3 which is disposed centrally.

In the cases where the plurality of third metal layer parts M3_1 to M3_3, the plurality of contact lines M3C_5 to M3C_7, the plurality of second metal layer parts M2_1 to M2_3 and the plurality of contact lines M2C_1 to M2C_3 are formed in the shape of prominences and depressions as illustrated in FIG. 4a, the stable junction of the bonding ball 420 may be possible since a contact area over which the bonding ball 420 is connected is increased.

FIG. 4b is the plan view of FIG. 4a. In an embodiment, referring to FIG. 4b, the two third metal layer parts M3_1 and M3_2, which are disposed at the outermost sides among the plurality of third metal layer parts M3_1 to M3_3, may be disposed on the contact lines M3C_5 and M3C_6 and may be arranged to form lines as, for example, illustrated in FIG. 4b.

Moreover, the one third metal layer part M3_3, which is disposed centrally among the plurality of third metal layer parts M3_1 to M3_3, may be disposed in the type of a line parallel to or substantially parallel to the third metal layer parts M3_1 and M3_2. The thicknesses of the third metal layer parts M3_1 and M3_2 may be the same with each other, and the third metal layer part M3_3 may be formed thinner than the third metal layer parts M3_1 and M3_2.

As is apparent from the above descriptions, according to the embodiments, the structure of a pad junction surface may be changed to be wide, whereby electrical resistance may be reduced and the physical junction between a pad and a bonding ball may be strengthened.

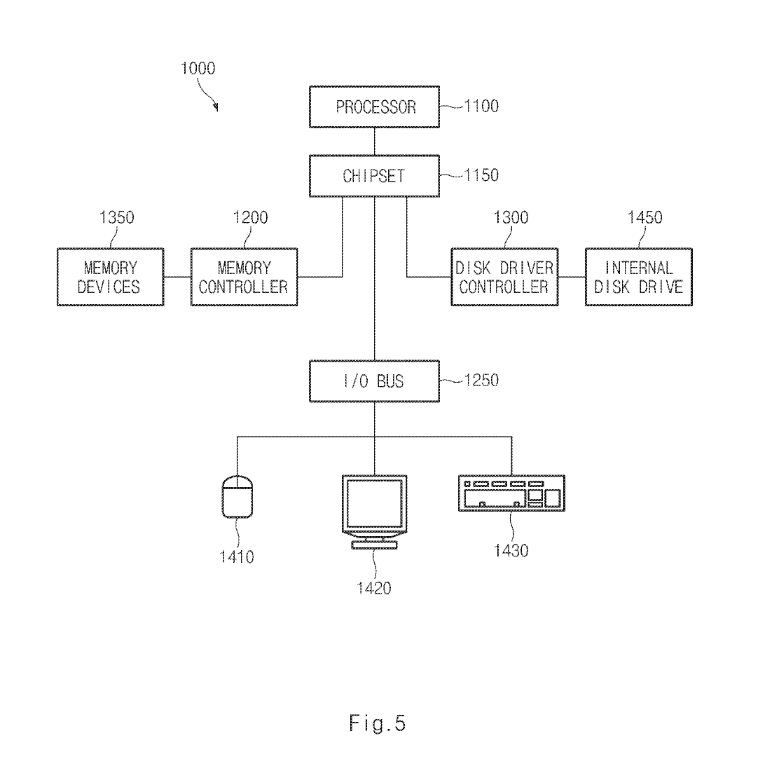

The semiconductor package discussed above (see FIGS. 1-4) are particular useful in the design of memory devices, processors, and computer systems. For example, referring to FIG. 5, a block diagram of a system employing the semiconductor packages in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor package as discussed above with reference to FIGS. 1-4. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor package as discussed above with relation to FIGS. 1-4, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 5 is merely one example of a system employing the semiconductor package as discussed above with relation to FIGS. 1-4. In alternate embodiments, such as cellular phones or digital cameras, the components may differ from the embodiments illustrated in FIG. 5.

While various embodiments have been described above, it will be understood to those skilled in the art that the embodiments described are by way of example only. Accordingly, the semiconductor package described herein should not be limited based on the described embodiments.

What is claimed is:

1. A semiconductor package comprising:
a lower metal layer configured for use as a bonding pad;
a plurality of upper metal layer parts formed over the lower metal layer, and separated from one another by gaps; and
a pad open region exposing the lower metal layer through spaces defined between the plurality of upper metal layer parts; and
a bonding ball positioned to bury the pad open region.

2. The semiconductor package according to claim 1, further comprising:
an insulation layer formed over the upper metal layer parts disposed at outermost sides among the upper metal layer parts, and allowing the spaces to pass through to the second metal layer.

3. The semiconductor package according to claim 1, further comprising:
a plurality of first contact nodes formed over the lower metal layer, and separated from one another by a predetermined gap.

4. The semiconductor package according to claim 3, wherein the number of first contact nodes is the same as the number of upper metal layer parts, and
wherein the first contact nodes are connected with the third metal layer parts.

5. The semiconductor package according to claim 3, wherein the first contact nodes are disposed in such a way as to define slits between them.

6. The semiconductor package according to claim 1, wherein the upper metal layer parts that are disposed centrally among the upper metal layer parts are disposed on the corresponding first contact nodes and are arranged in lines.

7. The semiconductor package according to claim 1, wherein the upper metal layer parts that are disposed centrally among the upper metal layer parts are disposed on the corresponding first contact nodes and are arranged to form substantially the shape of a quadrangle.

8. The semiconductor package according to claim 1, wherein the upper metal layer parts that are disposed centrally among the upper metal layer parts are disposed on the corresponding first contact nodes and are arranged to form substantially the shape of a mesh-shaped lattice.

9. The semiconductor package according to claim 1, wherein a bottom surface of the bonding ball is in contact with exposed portions of the lower metal layer, and side surfaces of the bonding ball are connected with side surfaces of the upper metal layer parts.

10. The semiconductor package according to claim 1, wherein the bonding ball is formed to cover top surfaces and both side surfaces of the upper metal layer parts that are disposed centrally among the upper metal layer parts.

11. The semiconductor package according to claim 1, wherein the lower metal layer is a second metal layer.

12. The semiconductor package according to claim 1, wherein the upper metal layer parts is a third metal layer.

13. The semiconductor package according to claim 1, wherein the lower metal layer is a first metal layer.

14. The semiconductor package according to claim 13, wherein the upper metal layer parts is a third metal layer.

15. The semiconductor package according to claim 14, further comprising:
a plurality of second metal layer parts formed over the lower metal layer, and separated from one another by a predetermined gap.

16. The semiconductor package according to claim 15, further comprising:
a plurality of second contact nodes formed over the second metal layer parts, and separated from one another by the preselected gap.
